(19) United States
(12) Patent Application Publication
(10) Pub. No.: US 2012/0187454 A1
(43) Pub. Date: Jul. 26, 2012

(54) NITRIDE SUBSTRATES, THIN FILMS, HETEROSTRUCTURES AND DEVICES FOR ENHANCED PERFORMANCE, AND METHODS OF MAKING THE SAME

(75) Inventors: Benjamin Haskell, Santa Barbara, CA (US); Paul T. Fini, Santa Barbara, CA (US)

(73) Assignee: INLUSTRA TECHNOLOGIES, LLC, Santa Barbara, CA (US)

(21) Appl. No.: 13/190,243

(22) Filed: Jul. 25, 2011

Related U.S. Application Data
(63) Continuation of application No. 12/128,399, filed on May 28, 2008, now abandoned.
(60) Provisional application No. 60/940,922, filed on May 30, 2007.

(51) Int. Cl. H01L 29/205; H01L 29/20

(52) U.S. Cl. 257/201; 257/615; 257/E29.089; 257/E29.081

(57) ABSTRACT

The present invention provides nitride semiconductors having a moderate density of basal plane stacking faults and a reduced density of threading dislocations, various products based on, incorporating or comprising the nitride semiconductors, including without limitation substrates, template films, templates, heterostructures with or without integrated substrates, and devices, and methods for fabrication of templates and substrates comprising the nitride semiconductors.

### CROSS REFERENCE TO RELATED APPLICATIONS

This application is a continuation of U.S. application Ser. No. 12/128,399 filed May 28, 2008 which is related to and claims the benefit of priority to U.S. Provisional Patent Application Ser. No. 60/940,922 filed May 30, 2007. Both of the foregoing applications are incorporated herein by reference in their entirety.

### TECHNICAL FIELD

The present invention relates to nitride semiconductors as well as substrates, thin films, templates, heterostructures and electronic devices based on, incorporating or comprising the nitride semiconductors and methods of making the same.

### BACKGROUND OF THE INVENTION

Gallium nitride and its alloys with indium, aluminum, and boron nitride have attracted significant attention in recent years due to the successful development of visible and ultraviolet light emitting diodes (LEDs), blue/violet laser diodes, and high-power electronic devices based on this materials system. Revolutions in lighting, display technology, data storage, and power switching are occurring as a result of the unique optical, electronic, and structural properties of this (Al, In, B, Ga)N semiconductor system, collectively referred to hereafter as “nitrides” or “nitride semiconductors” and defined herein below for purposes of the present application. Despite considerable progress, however, devices based on nitride semiconductors, including but not limited to laser diodes, light emitting diodes, photovoltaics, and power transistors (hereafter collectively referred to as “nitride devices”) have failed to attain their theoretical performance potential and have therefore remained too inefficient, too fragile, and too expensive for high-power commercial and consumer use.

Three of the major causes of this shortfall in device performance are polarization-related inefficiencies of conventional nitride devices, high defect densities in the nitride semiconductors, and poor conductivity of the nitrides. The inventors previously demonstrated a means of eliminating so-called polarization effects via the growth of planar nonpolar nitrides, as described in U.S. patent application Ser. Nos. 10/537,644, 10/537,385, and 11/140,893, as well as U.S. Pat. No. 7,186,302, which are all incorporated by reference herein in their entirety.

It should be understood that the nonpolar directions and planes of nitride semiconductors are those directions and planes having Miller-Bravais indices described by values hki0, in which h+k+i=0. With reference to FIG. 1 below, nitride semiconductors contain two families of nonpolar directions: the a-directions belonging to the (11 2̅0) family that includes the [11 2̅0], [1 2̅10], [ 2̅110], [ 1̅ 1̅20], [ 1̅2 1̅0], and [2 1̅ 1̅0] crystallographic directions; and the m-directions belonging to the <1 1̅00> family that includes the [1 1̅00], [10 1̅0], [01 1̅0], [0 1̅10], [ 1̅010], and [ 1̅100] directions. Further, the nonpolar planes are defined as planes having surface normals parallel to the twelve nonpolar directions indicated above. Thus, when referring to a-plane GaN, reference is made to any plane in the {11 2̅0} family of planes, which includes the (11 2̅0), (1 2̅10), ( 2̅110), ( 1̅ 1̅20}), ( 1̅2 1̅0), and (2 1̅ 1̅0) crystallographic planes; likewise, the m-planes include all of the members of the {1 1̅00} family, including the (1 1̅00), (10 1̅0), (01 1̅0), (0 1̅10), ( 1̅010), and ( 1̅100) planes. It should be noted that, neglecting the incorporation of impurities and dopants in the crystal, all nonpolar planes contain nominally equal numbers of group III atoms (e.g. Ga, Al, In, or B) and group V atoms (i.e. nitrogen).

It should further be understood that an alternate family of relevant directions and planes of nitride semiconductors are the basal planes. The two types of basal planes are the (0001) and (000 1̅) planes, which belong to the {0001} family of planes. Both planes in the {0001} family are referred to as “c-planes,” but they are chemically distinct. The (0001) plane contains only group III atoms or ions, whereas the (000 1̅) plane contains only group V atoms. The c-planes are also commonly referred to as “polar” planes in nitride semiconductors. The crystallographic directions that are perpendicular to the polar c-planes are the [0001] and [000 1̅] directions, and are referred to as the c-directions.

A further family of relevant planes in nitride semiconductors is the semipolar planes. The term “semipolar planes” can be used to refer to a wide variety of planes that possess at least two nonzero h, i, or k Miller indices and a nonzero/Miller index. Some commonly observed examples of semipolar planes include, but are not limited to, the {11 2̅2 }, {10 1̅1}, {10 1̅2 }, {10 1̅3 }, {10 1̅4}, and {20 2̅1} families of planes. These planes are inclined relative to both the nonpolar and polar planes; for example, the {10 1̅} and {10 1̅3} planes are at 62.98° and 32.06° to the c-planes, respectively.

It has been widely reported in the literature that nonpolar and semipolar nitrides grown via heteroepitaxial methods, meaning grown upon dissimilar templates or substrates, typically contain two classes of microstructural abnormalities: threading dislocations and basal plane stacking faults. Threading dislocations, or “dislocations” or “TDs,” can be thought of as defective lines through the semiconductor crystal existing due to insertion of extra half planes of atoms in the crystal lattice (in the case of pure edge dislocations), a torsional shearing of the crystal lattice (in the case of pure screw dislocations), or a combination of the two (in the case of mixed-character dislocations). The presence of threading dislocations in a semiconductor is almost universally recognized as being deleterious to material quality and device performance, as TDs serve as non-radiative recombination centers for electrons and holes traveling through the crystal.

Basal plane stacking faults, or “stacking faults” or “faults” or “SFs,” are an alteration of the stacking sequence in the crystal lattice along the c-direction. Referring to FIG. 2, basal plane stacking faults in GaN disrupt the normal 2H AαB βAαBβ layer sequence, where A and B layers contain only Ga atoms and α and β layers contain only nitrogen atoms, or visa versa. Three types of basal plane stacking faults have been predicted in gallium nitride. The typical 2H stacking sequence is shown in FIG. 2(a). The I₁ fault involves a displacement of the lattice of ⅓ [symbol] 1 1̅00 [symbol] plus the insertion or removal of a basal plane, resulting in the stacking sequence AαBβCγBβCγ, as is shown in FIG. 2(b). The I₂ fault is a simple displacement of the lattice of ⅓ [symbol] 1 1̅00 [symbol] , resulting in AαBβCγAαCγ stacking, as is shown in FIG. 2(c). The extrinsic, or E stacking fault is an insertion of a Cγ bilayer in the lattice, yielding AαBβCγAαBβ stacking as in FIG. 2(d). The faults in nonpolar GaN films are most commonly of type I₁, though other fault characters have been observed. Faults have been associated with redshifts of band-edge transitions in GaN films, but little else is known about their influence on the electronic properties of crystals that contain them.

Recently, McLaurin et al. reported increased carrier mobility along the directions perpendicular to the c-direction in m-plane GaN films containing faults, compared to conventional c-plane GaN {Appl. Phys. Lett. 86, 262104 (2005)}. Unfortunately, such films as were examined in McLaurin et al.'s work are of little use for device applications, as they were of sufficiently poor material quality such that achieving good device performance would be exceedingly difficult.

Electronic and optoelectronic devices could benefit significantly from the availability of nitride semiconductor substrates, templates, and heterostructures affording increased carrier mobility in the absence of deleterious structural defects.

### SUMMARY OF THE INVENTION

The present invention fulfills these needs and satisfies additional objects and advantages by providing nitride semiconductors having a moderate density of basal plane stacking faults and a reduced density of threading dislocations.

The present invention further provides various products based on, incorporating or comprising nitride semiconductors having a moderate density of basal plane stacking faults and a reduced density of threading dislocations, including without limitation substrates, template films, heterostructures with or without integrated substrates or templates, and devices.

The present invention also provides methods for fabrication of templates and substrates comprising nitride semiconductors having a moderate density of basal plane stacking faults and a reduced density of threading dislocations.

For purposes of describing the present invention, the term “nitride” or “nitride semiconductor” as used herein refers to a semiconductor material containing gallium nitride either alone or in combination with one or more of aluminum nitride, indium nitride and boron nitride, wherein the bulk composition of gallium nitride, aluminum nitride, indium nitride and boron nitride in the semiconductor material is given by the formula (AlₓB_{y}In_{z}Ga_{1-x-y-z})N, in which 0≦x≦1, 0≦y≦1, 0≦z≦1, and 0≦x+y+z≦1.

The most basic product embodiment within the scope of the present invention is a nonpolar gallium nitride (GaN) substrate comprising a nitride semiconductor having a moderate density of basal plane stacking faults and a reduced density of threading dislocations. This substrate can be used to produce a wide variety of higher performance (opto)electronic devices that similarly incorporate the nitride semiconductors of the present invention. Such nonpolar GaN substrates can be utilized with either an a-plane surface or an m-plane surface, or miscut variants of these two orientations. In both the a-plane and m-plane orientations, the basal plane stacking faults will intersect the substrate surface at an angle of approximately 90°, give or take any mis-orientation, intentional or unintentional, of the substrate's surface normal with respect to the closest nonpolar direction (referred to as “miscut”).

Another anticipated product embodiment is a polar c-plane gallium nitride substrate comprising a nitride semiconductor having a moderate density of basal plane stacking faults and a reduced density of threading dislocations. Such a substrate can have either an on-axis or miscut surface. In such a substrate, the conduction enhancement occurs within the plane of the substrate, and is useful for current spreading in a back-side contacted optoelectronic device.

Another anticipated product embodiment is a semipolar gallium nitride substrate comprising a nitride semiconductor having a moderate density of basal plane stacking faults and a reduced density of threading dislocations. Similar to the nonpolar substrate product described above, the stacking faults in the semipolar substrate would intersect the surface, albeit at an angle of inclination with respect to the surface normal, but would otherwise function in a similar manner to a nonpolar nitride substrate.

An embodiment of the present invention which is a variation of the above product embodiments is a gallium nitride substrate comprising a nitride semiconductor having a moderate density of basal plane stacking faults and a reduced density of threading dislocations which has been doped with one or more conductivity-altering dopants, including but not limited to Mg, Zn, Si, Ge, O, C, Be, Ca, Li and Fe. An exemplary embodiment of this is an Mg-doped GaN substrate that offers exceptional p-type conductivity throughout the substrate. Such a substrate would enable production of inverted optoelectronic devices with excellent back-side current spreading. Likewise, an n-type conductive substrate could be produced by the same method, in such case utilizing Si as the primary dopant, for non-inverted device structures.

Another embodiment of the present invention is a III-Nitride semiconductor having a moderate density of basal plane stacking faults and a reduced density of threading dislocations and a bulk composition other than gallium nitride, such as Al_{0.25}Ga_{0.75}N, or any other composition satisfying the formula (AlₓB_{y}In_{z}Ga_{1-x-y-z})N, in which 0≦x≦1, 0≦y≦1, 0≦z≦1, and 0≦x+y+z≦1. The substrate may contain any other element or ion in sub-percent level as dopants, such as Zn, Mg, Si, Ge, O, C, Be, Ca, Li, Fe and the like, or band gap modifiers, such as P, As and the like.

Yet another embodiment of the present invention is a substrate having a moderate density of basal plane stacking faults and a reduced density of threading dislocations, as described above, whose back side is coated or otherwise treated to serve a secondary purpose. For example, the back side of a GaN substrate can be coated with a yellow phosphor such that when a blue light emitting diode heterostructure-based device is grown on the substrate, an inverted device geometry is utilized, causing some of the blue light emitted from the heterojunction to be absorbed by the yellow phosphor and reemitted as yellow light. The combination of the blue light that passes through the phosphor layer and the yellow light emitted by the phosphor would produce white light. An alternate embodiment is a GaN substrate comprising a nitride semiconductor of the present invention, the back side of which has been selectively etched to form microlenses or pyramids. Such microlenses or pyramids can enhance light extraction through the substrate, improving the wall plug efficiency of an LED constructed according to the present invention.

A second class of products embodied by the present invention is template layers and templates based on, incorporating or comprising a nitride semiconductor having a moderate density of basal plane stacking faults and a reduced density of threading dislocations. A template layer for purposes of the present invention can be defined as a film comprising a III-Nitride semiconductor having a moderate density of basal plane stacking faults and a reduced density of threading dislocations and a bulk composition satisfying the formula (AlₓB_{y}In_{z}Ga_{1-x-y-z})N, in which 0≦x≦1, 0≦y≦1, 0≦z≦1, and 0≦x+y+z<1, that forms a template when deposited on a foreign substrate. The foreign substrate may include, but is not limited to, {0001} c-plane Al₂O₃, {1 1̅02} r-plane Al₂O₃, {1 1̅00} m-plane Al₂O₃, {11 2̅0} a-plane Al₂O₃, {0001} c-plane SiC, {1 1̅00} m-plane SiC, {11 2̅0} a-plane SiC, any semipolar plane of SiC, (100) γ-LiAlO₂, (100) MgAl₂O₄, (110) MgAl₂O₄, (111) MgAl₂O₄, and the like. Any of the variations described above for substrates, such as doping for conductivity control, variation of the crystallographic orientation of the template (for example,. m- versus a-plane), variation of the template composition and the like, or any combination of these features, can be utilized in the template layers and templates of the present invention.

A third class of products embodied by the present invention is homojunctions based upon, incorporating or comprising a nitride semiconductor having a moderate density of basal plane stacking faults and a reduced density of threading dislocations. A homojunction is two or more layers of non-identical doping or composition in contact with one another. The simplest embodiment of a homojunction is a so-called p-n junction, in which two layers of GaN are grown one above the other, one layer having been doped with a conductivity-modifying impurity such as Mg and the other having been doped with another conductivity-modifying impurity such as Si. In an alternate embodiment of the present invention, the substrate or template layer may serve as a component of the homojunction. For example, an n-type doped m-plane GaN substrate comprising a nitride semiconductor having a moderate density of basal plane stacking faults and a reduced density of threading dislocations can have a p-type GaN layer grown upon said substrate, creating a p-n homojunction.

A fourth class of products embodiment of this class of products is heterojunctions, or more generically heterostructures, based upon, incorporating or comprising a nitride semiconductor having a moderate density of basal plane stacking faults and a reduced density of threading dislocations, and further consisting of two or more nitride layers of dissimilar composition, such as alternating layers of AlGaN and GaN. To effectively incorporate the present invention, these multiple layers are grown upon either a substrate or template based upon, incorporating or comprising a nitride semiconductor having a moderate density of basal plane stacking faults and a reduced density of threading dislocations. An embodiment of this class of products is a heterostructure grown upon a template layer based upon, incorporating or comprising a nitride semiconductor having a moderate density of basal plane stacking faults and a reduced density of threading dislocations that is bonded to a carrier substrate so that the original substrate and/or template layer can then be removed.

The fifth class of products embodied by the present invention is fully integrated devices that incorporate substrates, templates, or heterostructures comprising a nitride semiconductor having a moderate density of basal plane stacking faults and a reduced density of threading dislocations. These devices would benefit from the enhanced carrier mobility provided in accordance with the present invention to enhance electrical efficiency, decrease heating, and generally improve performance. In general, the present invention can be broadly applied to a variety of electronic and optoelectronic devices based on the (Al,In,B,Ga)N materials system. For example, a light emitting diode (“LED”) can be produced that incorporates a substrate, template and/or heterostructure component comprising a nitride semiconductor having a moderate density of basal plane stacking faults and a reduced density of threading dislocations. A specific example of such a LED within the scope of the present invention is a blue InGaN—GaN light emitting diode having improved lateral current spreading characteristics and therefore improved wall-plug efficiencies compared to existing technologies. The present invention can similarly be utilized to reduce forward voltages in III-nitride-based laser diodes, an example of which would be a blue laser diode device consisting of a InGaN-based multiple quantum well (MQW) heterostructure grown upon an m-plane GaN substrate comprising a nitride semiconductor having a moderate density of basal plane stacking faults and a reduced density of threading dislocations. High electron mobility transistors based on GaN could benefit from enhanced lateral mobility via the present invention, allowing faster high-power transistors to be developed than are currently achievable.

### BRIEF DESCRIPTION OF THE DRAWINGS

Preferred and alternative embodiments of the present invention are described in detail below with reference to the following drawings.

FIG. 1 shows examples of a nitride semiconductor crystal structure and primary crystallographic directions, along with examples of nonpolar, polar and semipolar planes of nitride semiconductors.

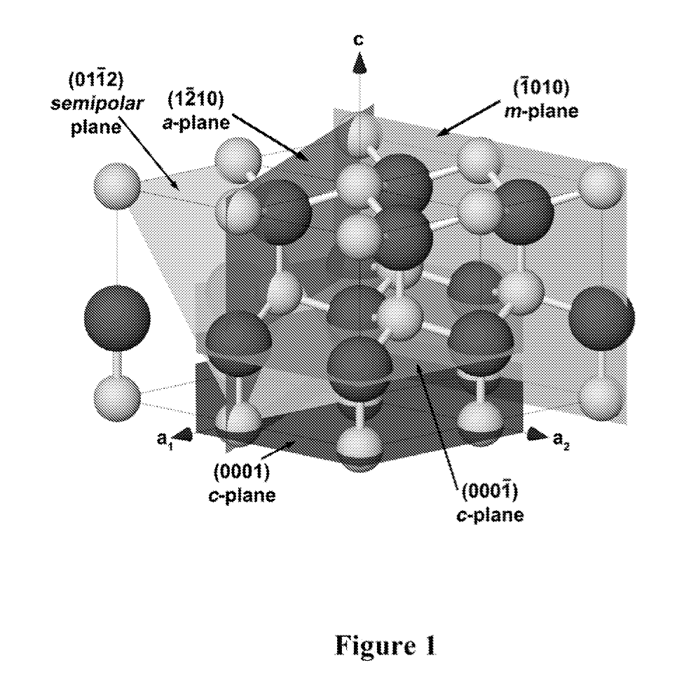

FIG. 2 shows the various basal plane stacking faults predicted for gallium nitride crystals.

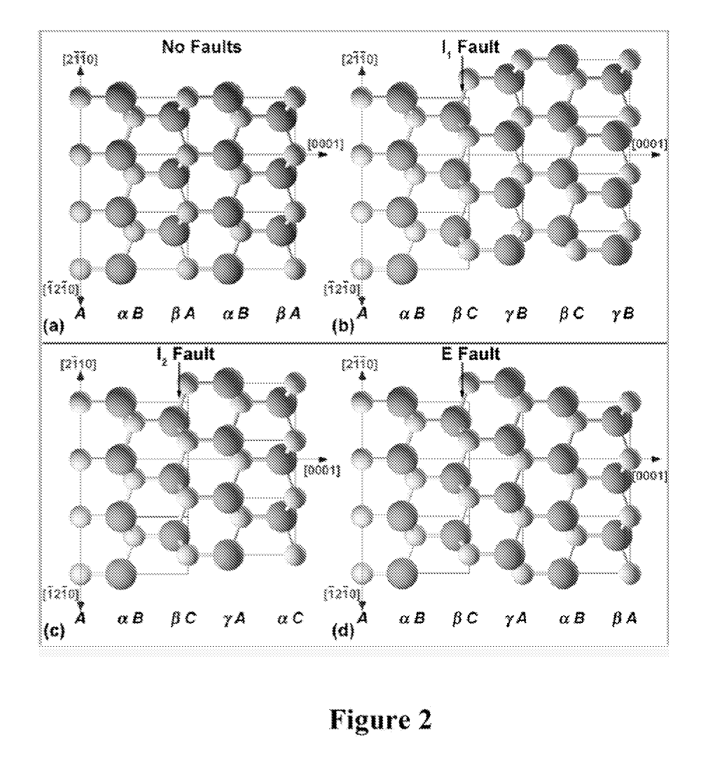

FIG. 3 illustrates a nitride semiconductor substrate containing basal plane stacking faults.

FIG. 4 illustrates a nitride semiconductor template containing basal plane stacking faults attached to a dissimilar substrate.

FIG. 5 illustrates a nitride semiconductor film or layer containing basal plane stacking faults attached to a nitride semiconductor substrate containing basal plane stacking faults.

FIG. 6 illustrates a nitride semiconductor heterostructure containing basal plane stacking faults attached to a nitride semiconductor substrate containing basal plane stacking faults.

FIG. 7 illustrates an electronic device containing a nitride semiconductor substrate containing basal plane stacking faults.

FIG. 8 is a block diagram illustrating methodology for the creation of nitride semiconductor substrates and templates containing basal plane stacking faults.

FIG. 9 is a block diagram illustrating alternate methodology for the creation of nitride semiconductor substrates and templates containing basal plane stacking faults.

### DETAILED DESCRIPTION OF THE PREFERRED EMBODIMENT

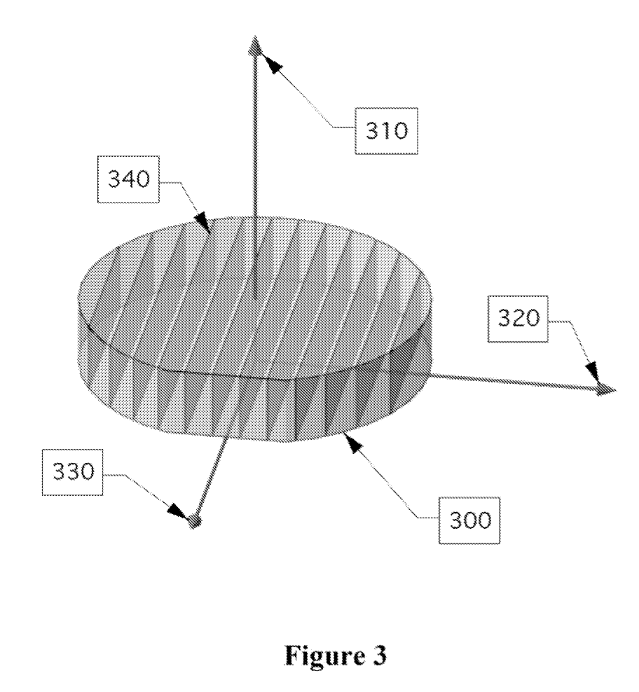

Referring now to FIG. 3, a substrate of the present invention comprising a nitride semiconductor having a moderate density of basal plane stacking faults and a reduced density of threading dislocations is shown. Block 300 represents a nitride semiconductor substrate comprising a crystalline matrix of (AlₓB_{y}In_{z}Ga_{1-x-y-z})N, in which 0≦x≦1, 0≦y≦1, 0≦z≦1, and 0≦x+y+z≦1. This substrate can range in thickness from about 40 μm to about 2 mm in thickness. More preferably, the thickness can range from about 250 μm to about 2000 μm. In other embodiments, the substrate thickness can range from about 50 μm to about 500 μm in thickness. However, the substrates of the invention can be of any conceivable thickness, limited only by practical considerations that are dictated by the application for which the substrate will be used. Most commonly, substrates having thicknesses ranging from about 250 μm to about 500 μm are desirable for device layer re-growth in the nitride semiconductor device industry. Block 310 identifies the surface normal direction, which in this case is parallel to one of the three primary crystallographic directions in the crystal. Blocks 320 and 330 are additional crystallographic directions in the material; Blocks 310, 320, and 330 are situated at 90° angles to one another. Block 340 represents a basal plane stacking fault in the crystal. In the particular embodiment set forth in FIG. 3, the crystallographic direction represented by Block 320 is normal to the fault plane, which makes this direction a c-direction. Also, the directions represented by Blocks 310 and 330 lie within the fault plane, and therefore can be described by Miller-Bravais indices satisfying the formula [hki0], where h+k+i=0. Most commonly, these two directions would be so-called “low-index” directions, with one belonging to the a-family of directions and the other to the m-family of directions. However, the invention can be generalized to include a crystal of arbitrary orientation in which Blocks 310, 320, and/or 330 may represent any three orthonormal directions in the crystal. The critical factor in the embodiment of the invention set forth in FIG. 3 is that the substrate represented by Block 300 contain some non-negligible density of stacking faults (Block 340), typically but not exclusively with these faults situated on the basal planes of the crystal lattice. In certain embodiments, the stacking fault density ranges from about 10³ cm⁻² to about 10⁷ cm⁻². In other embodiments, the stacking fault density ranges from about 10⁶ cm⁻² to about 5×10⁶ cm⁻². In additional embodiments, the stacking fault density is at least about 10² cm⁻². In further embodiments, the stacking fault density is at least about 10⁶ cm⁻².

A second key element of the embodiment of the invention set forth in FIG. 3 is that it is represented to be largely “free” of threading dislocations. The most preferable embodiment of the invention would include exactly zero threading dislocations. However, the threading dislocation density need not be exactly zero for the invention to be applicable. Also, it is unnecessary to achieve such a nonexistent threading dislocation density for nitride devices to function properly or benefit from the present invention. Indeed, any density of threading dislocations no greater than about 5×10⁸ dislocations per square centimeter of surface area of the substrate is adequate for the practice of the invention. More preferably, the threading dislocation density is no greater than about 5×10⁶ cm⁻² for the practice of the present invention. In other embodiments, threading dislocation density ranges from about 0 to about 10⁹ cm⁻². In further embodiments, the threading density is no greater than than about 10⁷ cm⁻². It should be noted that the term “threading dislocations” as used here specifically excludes “partial dislocations.” Partial dislocations exist at the boundary between faulted and unfaulted material (i.e. on the periphery of finite-area stacking faults) in the nitride crystal. Any density of partial dislocations in the crystal is acceptable for the practice of the invention.

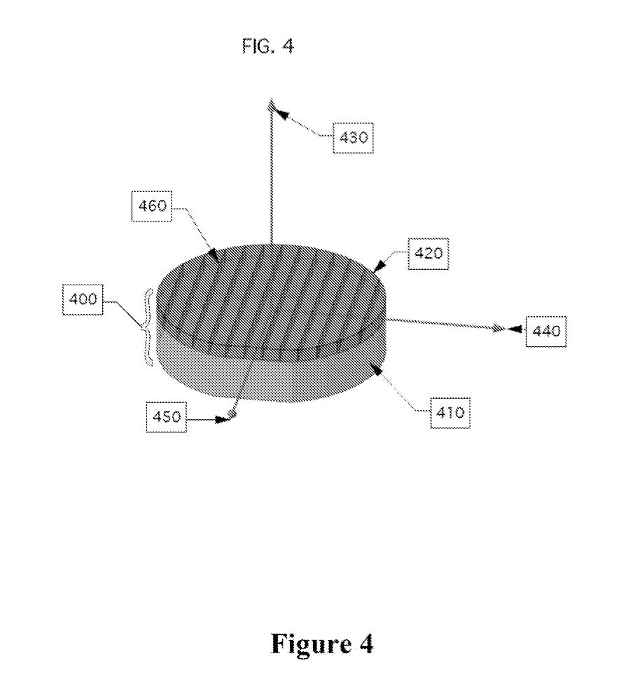

FIG. 4 represents an alternative embodiment of the invention, namely a template comprising a nitride film 420 attached to a dissimilar substrate 410. Block 400 represents the combination of the nitride film 420 and the dissimilar substrate 410. The nitride film 420 comprises a nitride semiconductor having a moderate density of basal plane stacking faults and a reduced density of threading dislocations. The directions represented by Blocks 430, 440, and 450 have the same meaning as Blocks 310, 320, and 330 in FIG. 3. Likewise, Block 460 here represents a fault in the material as Block 340 did in FIG. 3. The nitride film 420 ideally possesses all of the properties of the free-standing substrate set forth in FIG. 3 above, including the stacking fault densities and threading dislocation densities for the substrate set forth above, except that the nitride film 420 would normally be thinner than the free-standing substrate, and the film would be fixed to the dissimilar substrate. The film thickness can range from about 100 nm to about 1000 μm. More preferably, the film thickness can range from about 1 μm to about 50 μm. In other embodiments, the film thickness can range from about 50 nm to about 2000 μm.

The dissimilar substrate 410 can be any glassy, metallic, ceramic, or semiconductor material; and may be either amorphous, polycrystalline, or single-crystal. The dissimilar substrate can serve one or more purposes. Principally, the dissimilar substrate provides mechanical stability to the nitride film 420. As the nitride film thickness is in many cases 50 μm or less, it is beneficial to attach the nitride film to a dissimilar substrate to protect the film from fracture due to its low thickness. To utilize this mechanical stability feature of the dissimilar substrate, the nitride film may be either grown (deposited) upon the dissimilar substrate, or it may be grown elsewhere and subsequently bonded, in whole or in part, to the dissimilar substrate. Methodology for each of these approaches is set forth hereinbelow.

An additional, optional role of the dissimilar substrate 410 is to provide a good lattice match to the orientation of the nitride film 420 such that the nitride film can be grown upon the substrate. For example, (100) γ-LiAlO₂, {1 1̅00} 4H—SiC, and {1 1̅00} 6H—SiC are suitable choices of dissimilar substrates for producing nitride films comprising a nitride semiconductor having a moderate density of basal plane stacking faults and a reduced density of threading dislocations and being oriented with m-plane primary free surfaces. Also as an example, {10 1̅2} Al₂O₃, {11 2̅0} 4H—SiC, and {11 2̅0} 6H—SiC are suitable choices of dissimilar substrates for producing nitride films comprising a nitride semiconductor having a moderate density of basal plane stacking faults and a reduced density of threading dislocations and being oriented with a-plane primary free surfaces. (AlₓB_{y}In_{z}Ga_{1-x-y-z})N substrates are also considered dissimilar if either 1) the properties of the substrate do not incorporate the principal features of the present invention (moderate basal plane stacking fault and reduced threading dislocation densities), or 2) the chemical composition of the substrate is different from that of the nitride film to be grown. It should be noted that the above examples do not limit the range of applicable dissimilar substrates. Suitable foreign substrates include, but are not limited to, {0001} c-plane Al₂O₃, {1 1̅02} r-plane Al₂O₃, {1 1̅00} m-plane Al₂O₃, {1120} a-plane Al₂O₃, {0001} c-plane SiC, {1 1̅00} m-plane SiC, {11 2̅0} a-plane SiC, any semipolar plane of SiC, (100) γ-LiAlO₂, (100) MgAl₂O₄, (110) MgAl₂O₄, (111) MgAl₂O₄, and the like. One skilled in the art will recognize that other examples of materials can be used in accordance with the present invention without limiting its applicability.

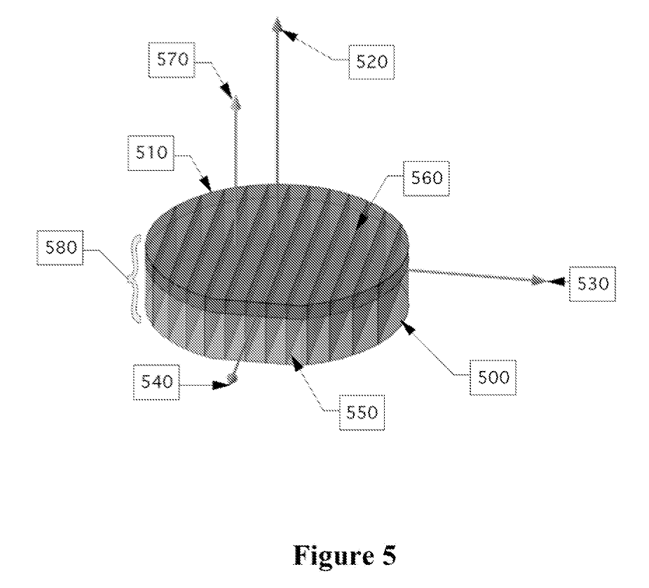

FIG. 5 is a representation of an alternate embodiment of the present invention. Block 500 represents a nitride substrate or template, akin to Blocks 300 and 400 in FIGS. 3 and 4, respectively, in that it incorporates the features of the invention (moderate density of basal plane stacking faults and a reduced density of threading dislocations) described above for Blocks 300 and 400. The crystallographic orientation of the substrate or template, as applicable, are described by the three crystallographic axes 520, 530, and 540, which are analogous to axes 310, 320, and 330 in FIG. 3 and axes 430, 440, and 450 in FIG. 4. Block 510 represents a nitride semiconductor layer of dissimilar composition to the substrate or template 500. Such bilayer structures can be thought of as homojunctions if the difference in composition between the substrate/template 500 and film layer 510 is primarily the dopant or lack thereof incorporated into each element 500 and 510. Alternately, if the substrate/template 500 and film 510 have different nitride compositions (i.e. the substrate 500 is GaN and the film 510 is In_{0.05}Ga_{0.95}N), the structure would be considered a simple heterojunction. Block 580 represents the combination of the nitride substrate or template 500 and the nitride semiconductor layer or layers 510. Block 550 represents stacking faults in the substrate or template 500. Block 560 represents stacking faults in the nitride semiconductor layer or layers 510. A key element of the Block 580 structure is that by selecting an appropriate surface orientation 570 with respect to the crystallographic axes 520, 530, and 540, the faults in the substrate or template 500 will propagate into the heterostructure region 510, thereby imparting the advantageous properties of the substrate or template (moderate density of basal plane stacking faults and a reduced density of threading dislocations) to the heterostructure region 510. In particular, the angle between surface normal 570 and the nitride crystallographic c-axis, represented by Block 520, 530, or 540, should be greater than zero. The propagation of the faults from the substrate or template 500 to the heterostructure 510 will be maximized for angles of approximately 90°, and minimized for angles of approximately 0°.

There are many examples of valid implementations of the embodiment shown in FIG. 5. Without limiting the scope of the present invention, one exemplary embodiment of such a structure is provided here. The simplest exemplary embodiment is one in which Block 500 represent an a- or m-plane GaN substrate having a moderate density of basal plane stacking faults and a reduced density of threading dislocations and having been doped with sufficient Si to make it n-type conductive, and block 510 represent a GaN film having been doped with sufficient Mg to make it p-type conductive. The combination of blocks 500 and 510 in this instance constitutes a homojunction, suitable for the formation of a pn diode.

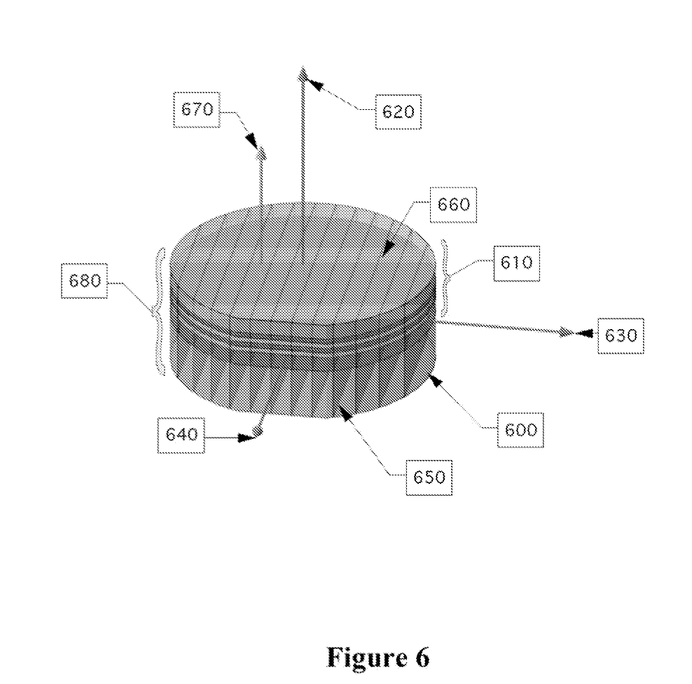

FIG. 6 is a representation of an alternate embodiment of the present invention. Block 600 represents a nitride substrate or template, akin to Blocks 300, 400, and 500 in FIGS. 3, 4, and 5, respectively, in that it incorporates the features of the invention (moderate density of basal plane stacking faults and a reduced density of threading dislocations) described above for Blocks 300, 400, and 500. The crystallographic orientation of the substrate or template, as applicable, are described by the three crystallographic axes 620, 630, and 640, which are analogous to axes 310, 320, and 330 in FIG. 3, axes 430, 440, and 450 in FIG. 4, and axes 520, 530, and 540 in FIG. 5. Block 610 represents multiple nitride semiconductor layers of similar or dissimilar composition to the substrate or template 600. Block 650 represents stacking faults in the substrate or template 600. As in FIG. 5, a key element of the Block 680 structure is that by selecting an appropriate surface orientation 670 with respect to the crystallographic axes 620, 630, and 640, the faults in the substrate or template 600 will propagate into the region 610, thereby imparting the advantageous properties of the substrate or template (moderate density of basal plane stacking faults and a reduced density of threading dislocations) to the region 610. The complete structure 680 is considered to be a heterostructure. An exemplary embodiment is one in which the substrate 600 is an undoped a- or m-plane GaN substrate having a moderate density of basal plane stacking faults and a reduced density of threading dislocations, and the heterostructure 610 comprises a n-type GaN layer having a thickness of about 500 nm, followed by a two-period InGaN/GaN multiple quantum well structure having layer thicknesses of about 10 nm each, capped by a p-type, Mg-doped GaN cap layer having a thickness of about 200 nm. This simplified multiple quantum well structure takes on all of the beneficial characteristics of the substrate (moderate density of basal plane stacking faults and a reduced density of threading dislocations), and is suitable for the production of a high-performance blue laser diode device. This exemplary embodiment is for illustrative purposes only, and should not be construed to limit the applicability of the present invention to other heterostructure arrangements or compositions. One skilled in the art will recognize that many variations of heterostructure design are compatible with the present invention, without fundamentally deviating from the scope of the present invention.

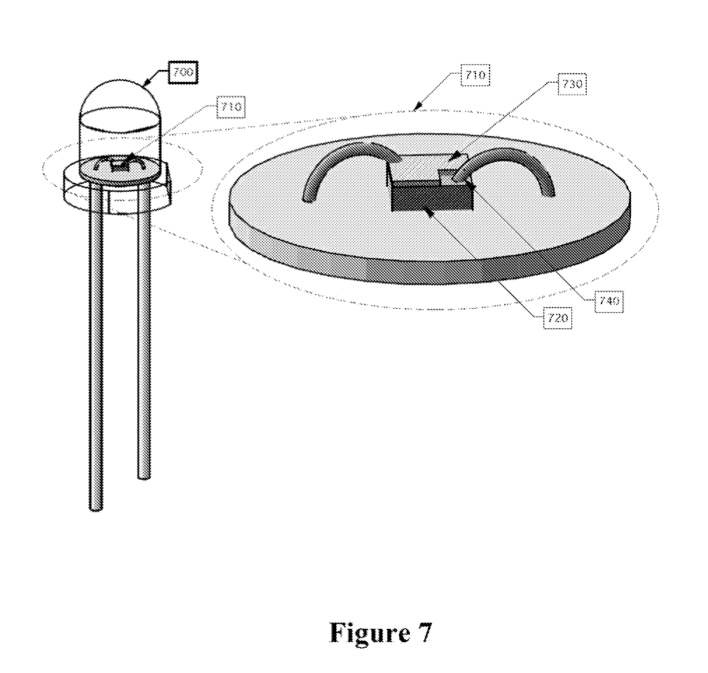

FIG. 7 illustrates a higher-level implementation of the present invention. Block 700 represents a packaged device incorporating the invention. In the particular exemplary embodiment shown in FIG. 7, the device is an optoelectronic device, such as a light emitting diode or laser diode. Block 710 represents a nitride semiconductor chip that has been encased in suitable packaging for the device application of interest. Block 720 shows an enlarged view of the chip 710. The nitride semiconductor chip is a small piece of the substrate/heterostructure hybrid collectively described by Blocks 600 and 610 in FIG. 6. In this case, Block 720 represents a small fragment of the substrate or template 600, and Block 730 represents a fragment of comparable breadth of the nitride heterostructure layer 610. The size of the chip 710 is typically in the range of about 0.2 mm to about 2 mm on a side, though both smaller or larger chip sizes are compatible with the present invention. Block 740 represents one or more electrical contacts to the chip 720. One or more of these contacts 740 may be located on the underside of the chip. Many variations of the device implementation described by FIG. 7 are possible within the scope of the present invention, so long as they include at least a substrate having a moderate density of basal plane stacking faults and a reduced density of threading dislocations, and/or one or more nitride layers having a moderate density of basal plane stacking faults and a reduced density of threading dislocations.

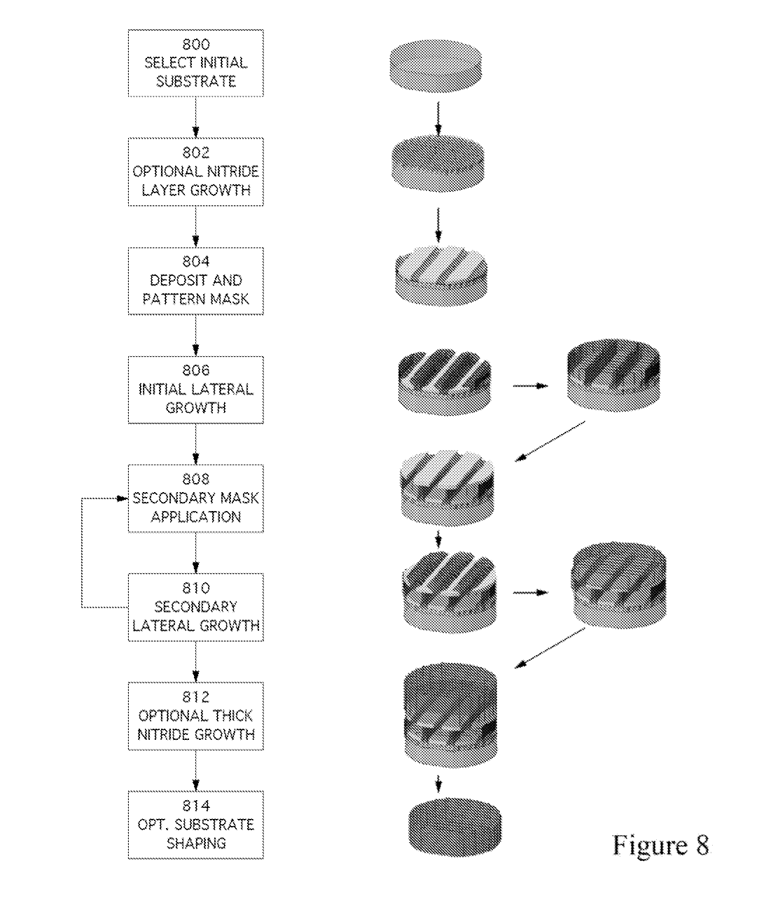

Several methods have been discovered which can be used to create the templates and substrates of the present invention. One such approach is described by the flow diagram shown in FIG. 8, and is referred to as the iterative lateral growth approach.

Referring now to FIG. 8, Block 800 represents the selection of an initial substrate for the growth process. The substrate preferably should provide a good lattice match to either the m- or a-plane of the nitride composition to be subsequently grown. Exemplary substrates include the substrates described above with respect to the template implementation of the invention, including without limitation (100) γ-LiAlO₂, {1 1̅00} 4H—SiC, and {1 1̅00} 6H—SiC in the case where orientation with m-plane primary free surfaces is desired and {10 1̅2} Al₂O₃, {11 2̅0} 4H—SiC, and {11 2̅0} 6H—SiC in the case where orientation with a-plane primary free surfaces is desired.

Block 802 represents the optional epitaxial growth of a nitride film upon the initial substrate. In this step, a nitride film, most preferably GaN though any nitride composition satisfying the formula (AlₓB_{y}In_{z}Ga_{1-x-y-z})N, in which 0≦x≦1, 0≦y≦1, 0≦z≦1, and 0≦x+y+z≦1 is acceptable, is deposited on the substrate of 800 via heteroepitaxial growth. The growth technique that can be used for this deposition includes, but is not limited to, molecular beam epitaxy (MBE), metalorganic chemical vapor deposition (MOCVD), hydride vapor phase epitaxy (HVPE), liquid phase epitaxy (LPE), or combinations of any of the above techniques. The best deposition technique to use will in general depend on the choice of substrate. For example, MBE is generally a preferable deposition technique for this initial nitride film layer when a- or m-plane SiC substrates are selected, whereas HVPE is preferable when r-plane Al₂O₃ substrates are used. Depending on the choice of substrate, this layer 802 may be omitted entirely. In this heteroepitaxial growth process, both stacking faults and threading dislocations will be generated in the nitride film. The subsequent process steps will preserve the stacking faults of the nitride film while selectively removing the threading dislocations from the layers deposited above the nitride film.

Block 804 represents deposition and patterning of a mask layer. Any material that resists deposition of the nitride semiconductor material to be subsequently grown is acceptable for this mask layer. In the preferred embodiment, the mask material is a dielectric material, most preferably SiO₂. The mask layer thickness may vary from roughly about 50 to about 10,000 nm, though the thickness should preferably be about 100 to about 150 nm, and most preferably approximately 130 nm in thickness. Other possible mask materials include, but are not limited to, W, TiN, Si₃N₄, HfO₂, and other dielectric and high-melting temperature metallic materials. The deposition method for the mask layer will depend on the composition and desired thickness of the mask layer. The preferred deposition technique is plasma-enhanced chemical vapor deposition for SiO₂ masks. However, electron beam evaporation, inductively coupled plasma deposition, and sputtering can also be used and have been demonstrated to be effective for this deposition step.

Block 804 further represents patterning the mask to selectively expose regions of the underlying nitride film layer of 802 or substrate of 800 (in the absence of a film layer). The patterning technique will generally utilize conventional photolithographic processing techniques coupled with an established etching technique that is suitable for the chosen mask material. In the preferred embodiment, in which an SiO₂ mask is used, conventional wet eching with an aqueous 10% HF solution is a simple and effective mask etching technique. A variety of mask geometries may be used in the practice of the present invention. The choice of mask geometries will depend primarily on the desired crystallographic orientation of the nitride film to be grown upon the mask layer. In the preferred embodiment, the most useful mask geometry is a pattern of alternating open and closed stripes aligned along the growing film's c-axis. However, one skilled in the art will recognize that many other mask geometries are useful in the practice of the invention.

Block 806 represents an initial lateral nitride growth step. This step involves the selection of a nitride film composition, most preferably GaN though any nitride composition satisfying the formula (AlₓB_{y}In_{z}Ga_{1-x-y-z})N, in which 0≦x≦1, 0≦y≦1, 0≦z≦1, and 0≦x+y+z≦1 that does not deposit on the mask material of 804 is acceptable. A growth technique must also be selected for the lateral growth of the nitride layer. HYPE is the preferred growth technique, though MOCVD is also a suitable technique. Other growth methods can also be used, provided that they demonstrate growth selectivity between the open and mask-covered areas, and yield nitride layers of high crystalline quality. The lateral nitride growth step involves growth of the nitride film vertically through the openings in the mask layer, then laterally over the mask layer. It is preferable, though not required, to continue the lateral growth process until adjacent portions of the growing nitride layer converge with one another above the mask layer, forming a continuous lateral growth layer. A key element of this step is that stacking faults that are present in the underlying nitride film layer of 802 or substrate of 800 will propagate into some or all of the laterally growing material. Alternately, the mask pattern of 806 may be selected specifically to cause the generation of new stacking faults in the laterally growing layer.

Block 808 represents repeating the mask layer deposition and patterning step 804, while block 810 represents repeating the lateral growth step 806. The mask geometry to be used will depend on the initial mask layer geometry and the crystallographic orientation of the growing nitride film. For example, for an a-plane GaN film orientation and a mask having parallel open and closed stripes oriented along the c-axis of the GaN film, the lateral location of the second mask layer of 808 should be directly above the first mask layer. In contrast, for an m-plane GaN film layer with a mask having open and closed stripes oriented along the c-axis, the repeated mask layer should again be parallel stripes but in this instance offset with respect to the lower mask layer. A wide variety of mask alignment options and subsequent lateral growth procedures are compatible with the present invention.

Indeed, the mask need not contain a regular pattern, but can be formed of randomly oriented pores in a thin masking film. For instance, an alternate approach to the ex situ mask deposition process thus described would be the use of in situ nanomasking. In this approach, a very thin, porous mask layer is deposited within the group III-nitride growth system such that the nitride film may grow vertically through the pores in the mask and laterally over the masked surface. An example of this approach would be the in situ deposition of a silicon nitride mask within an HVPE crystal growth system immediately preceding the lateral growth step represented by block 806. The key feature of the masking and lateral growth steps is that threading dislocations that are present in the earlier lateral growth layer or layers are blocked from further propagation by the subsequent mask layer or layers, and that stacking faults from the first lateral growth layer can propagate into the subsequent lateral growth layer or layers. These steps 808 and 810 may be repeated as necessary until the final lateral growth layer exhibits an acceptably low threading dislocation density yet contains a sufficient stacking fault density to be useful for the present invention.

Block 812 represents an optional thick nitride growth process. If the desired product from the above steps is a template layer, this step is generally omitted. However, if the desired product is a free-standing nitride substrate, then this thick-film growth process is generally performed. The preferred growth technique for this step is generally HVPE. However, other growth techniques, including those described above as well as physical vapor transport (PVT) and ammonothermal growth, can also be used for this step. The nitride film should be grown to a sufficient thickness to be removable from the initial substrate intact, typically about 100 to about 1000 μm in thickness. The upper limit for film thickness is limited only by the capacity of the growth system used for this step. A critical element of this step is that stacking faults generated in the lower layers must propagate into the thick nitride film. Selection of the proper growth direction, namely any nonpolar or semipolar growth direction, will yield this fault propagation.

Block 814 represents the optional removal of the initial substrate and/or lateral growth layers. A wide variety of initial substrate removal techniques can be used, including but not limited to dry etching, laser assisted lift-off, wet etching, sawing, mechanical or chemical-mechanical polishing, or spontaneous in situ separation techniques. Some cutting, polishing, and/or shaping of the resulting free-standing nitride substrate is often necessary or desirable to yield a substrate of ideal size and shape for subsequent use in device layer growth.

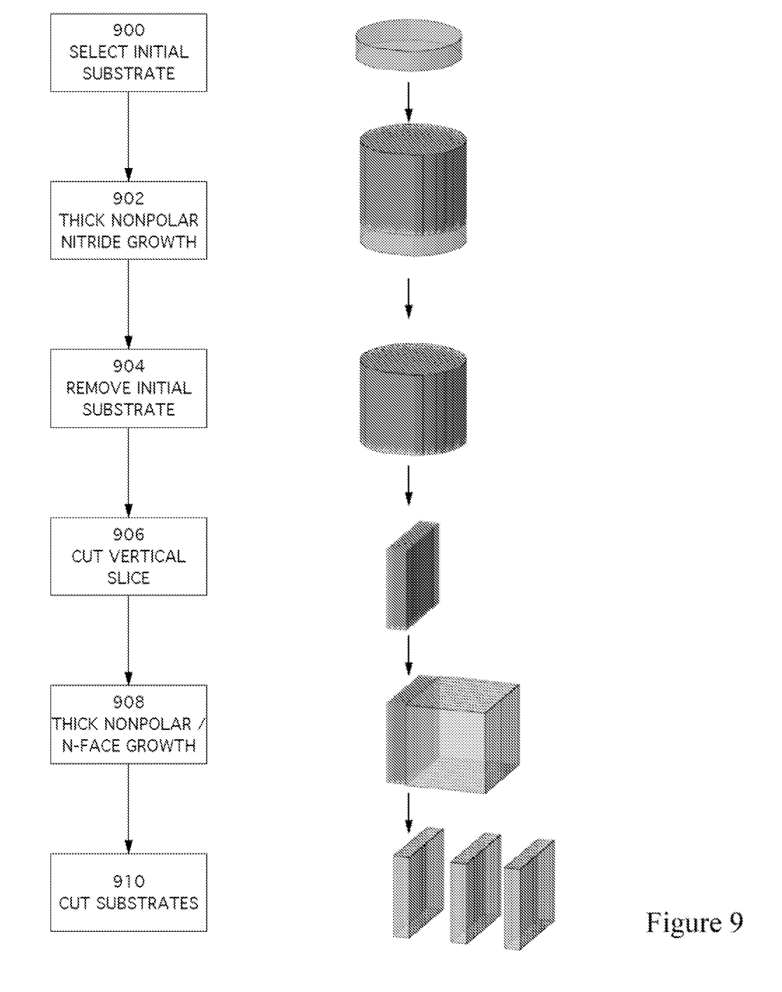

The exemplary methodology described by the flow diagram shown in FIG. 8 and discussed in detail above is capable of yielding high-quality substrates and templates containing a moderate density of basal plane stacking faults and a reduced density of threading dislocations for successful practice of the present invention. An alternate approach is described in FIG. 9.

Referring now to FIG. 9, an initial substrate (Block 900) is selected as described for Block 800 above, and a thick nonpolar GaN layer (Block 902) is grown upon the initial substrate. A surface 904 is then presented for further growth either by selecting a natural nonpolar crystal facet or by cutting a desired nonpolar plane at 90° to the initial nonpolar plane, exposing stacking faults at the free surface without exposing threading dislocation terminations and thereby yielding a cut vertical slice 906. As shown in Block 908, a second thick nonpolar GaN crystal is then grown from the exposed faulted surface, yielding a thick nitride semiconductor crystal containing a high density of stacking faults but a low threading dislocation density. This growth step may follow previously disclosed methods, such as those described in U.S. Pat. No. 7,220,658, which is incorporated by reference herein in its entirety. The exact growth method of conducting the thick growth step illustrated by Block 808 is immaterial to the practice of the invention so long as the substrate or template for that growth step, represented by Block 806, possesses the key features of the invention, namely a moderate density of basal plane stacking faults and a reduced density of threading dislocations.

Device layers or heterostructures grown upon the structured substrates or templates of the present invention will benefit from the enhanced lateral conductivity provided by the combined presence of a moderate density of basal plane stacking faults and a reduced density of threading dislocations. Several examples of heterostructures that utilize the present invention are described hereinabove. To summarize the application of this invention to heterostructures, a heterostructure is grown upon a template or substrate that incorporates the invention in that it contains a moderate density of basal plane stacking faults and a reduced density of threading dislocations at its free surface. As long as the template's or substrate's surface normal is not exactly parallel to the würtzite c-axis, the stacking faults will propagate into the heterostructure, thereby imparting the benefits of the invention to the hetero structure.

Functional optoelectronic and electronic devices, such as blue, green, and white light emitting diodes and blue and green laser diodes, among others, may benefit from this invention in that they may be formed via heterostructures that contain a moderate density of basal plane stacking faults and a reduced density of threading dislocations.

It will be understood that the present disclosure is not limited to the embodiments disclosed herein as such embodiments may vary somewhat. It is also to be understood that the terminology employed herein is used for the purpose of describing particular embodiments only and is not intended to be limiting in scope and that limitations are only provided by the appended claims and equivalents thereof

All publications and patents mentioned herein are incorporated herein by reference for the purpose of describing and disclosing, for example, the constructs and methodologies that are described in the publications, which might be used in connection with the presently described invention. The publications discussed above and throughout the text are provided solely for their disclosure prior to the filing date of the present application. Nothing herein is to be construed as an admission that the inventors are not entitled to antedate such disclosure by virtue of prior invention.

The embodiments of the invention in which an exclusive property or privilege is claimed are defined as follows:

1. A substrate comprising a nitride semiconductor wherein the nitride semiconductor comprises a composition containing at least about 98% Al, B, In, Ga, and N atoms by number and the substrate comprises a crystalline lattice that is principally of the hexagonal würtzite structure having a stacking fault density of at least about 10² cm⁻² and a threading dislocation density of no greater than about 5×10⁸ cm^{-2.}

2. The substrate according to claim 1 having a thickness of about 50 μm to about 2000 μm.

3. The substrate according to claim 1 having a stacking fault density of at least about 10⁶ cm⁻².

4. The substrate according to claim 1 wherein the nitride semiconductor is doped with conductivity-modifying atoms or ions.

5. The substrate according to claim 4 wherein the conductivity-modifying atoms or ions are one or more of Zn, Be, Mg, Fe, O, or Si.

6. The substrate according to claim 1 having a threading dislocation density no greater than about 5×10⁶ cm⁻².

7. The substrate according to claim 1 having a surface that is either c-plane, a-plane, m-plane or semipolar plane oriented.

8. A nitride film comprising a nitride semiconductor wherein the nitride semiconductor comprises a composition containing at least about 98% Al, B, In, Ga, and N atoms by number and the substrate comprises a crystalline lattice that is principally of the hexagonal würtzite structure having a stacking faults density of at least about 10² cm⁻² and a threading dislocation density of no greater than about 5×10⁸ cm^{-2.}

9. A template comprising the nitride film according to claim 8 and a substrate of dissimilar composition or microstructure compared to the template film.

10. The template according to claim 9 wherein the substrate of dissimilar composition or microstructure comprises Al₂O₃, LiAlO₂, SiC, MgAl₂O₄, or a nitride semiconductor having the formula (AlₓB_{y}In_{z}Ga_{1-x-y-z})N, in which 0≦x≦1, 0≦y≦1, 0≦z≦1, and 0≦x+y+z≦1.

11. The template according to claim 10 wherein the substrate of dissimilar composition or microstructure comprises AN, InN, GaBN, AlGaN or AlInGaN.

12. The nitride film according to claim 8 having a thickness ranging from about 50 nm to about 2,000 μm.

13. The nitride film according to claim 8 having a stacking fault density of at least about 10⁶ cm⁻².

14. The nitride film according to claim 8 wherein the nitride semiconductor is doped with conductivity modifying atoms or ions.

15. The nitride film according to claim 14 wherein the conductivity modifying atoms or ions are one or more of Zn, Be, Mg, Fe, O, or Si.

16. The nitride film according to claim 8 having a threading dislocation density no greater than about 5×10⁶ cm⁻².

17. The nitride film according to claim 8 having a surface that is either c-plane, a-plane, m-plane or semipolar plane oriented.

18. A homojunction grown upon the substrate according to claim 1.

19. A homojunction grown upon the template according to claim 9.

20. A heterostructure grown upon the substrate according to claim 1.
